(19) United States
(12) Patent Application Publication
(10) Pub. No.: US 2026/0354046 A1
(43) Pub. Date: Nov. 5, 2026

(54) RESISTIVE RANDOM-ACCESS MEMORY (RRAM) DEVICES FOR HIGH-TEMPERATURE APPLICATIONS

(71) Applicant: TetraMem Inc., Fremont, CA (US)

(72) Inventors: Minxian Zhang, Amherst, MA (US); Ning Ge, Danville, CA (US)

(73) Assignee: TetraMem Inc., Fremont, CA (US)

(21) Appl. No.: 19/194,064

(22) Filed: Apr. 30, 2025

(51) Int. Cl. H10N 70/00; H10B 63/00; H10N 70/20

(52) U.S. Cl. CPC H10N 70/841; H10B 63/00; H10N 70/011; H10N 70/24; H10N 70/8833

(57) ABSTRACT

Resistive random-access memory (RRAM) devices for high-temperature applications and methods for fabricating the same are provided. An RRAM device may include a first electrode, a switching oxide layer comprising a switching oxide, and a second electrode. The switching oxide may be HfOₓ, TaO_{y}, ZrO_{z}, etc. The first electrode comprises a first electrode material that is non-reactive to the switching oxide and presents high thermal stability, such as platinum (Pt), iridium (Ir), palladium (Pd), carbon, chromium (Cr), ruthenium (Ru), titanium nitride (TiN), tantalum nitride (TaN), or a conductive ceramic. The second electrode comprises a second electrode material that is reactive to the switching oxide, such as tantalum (Ta), hafnium (Hf), tungsten (W), molybdenum (Mo), zirconium (Zr), or niobium (Nb). The RRAM device may further include one or more interface layers positioned between the first electrode and/or the second electrode and the switching oxide layer and/or embedded within the switching oxide layer.

### TECHNICAL FIELD

The implementations of the disclosure relate generally to resistive random-access memory (RRAM) devices and, more specifically, to RRAM devices suitable for high temperature applications and methods for fabricating the same.

### BACKGROUND

A resistive random-access memory (RRAM) device is a two-terminal passive device with tunable and non-volatile resistance. The resistance of the RRAM device may be electrically switched between a high-resistance state (HRS) and a low-resistance state (LRS) by applying suitable programming signals to the RRAM device. RRAM devices may be used to form crossbar arrays that may be used to implement in-memory computing applications, non-volatile solid-state memory, multi-level memory, image processing applications, neural networks, etc.

### SUMMARY

The following is a simplified summary of the disclosure to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects of the present disclosure, a resistive random-access memory (RRAM) device is provided. The RRAM device includes: a first electrode including a first electrode material; a switching oxide layer including a switching oxide; and a second electrode fabricated on the switching oxide layer, wherein the first electrode material is not reactive to the switching oxide, wherein the second electrode includes a second electrode material that is reactive to the switching oxide, and wherein the second electrode material includes at least one of tantalum (Ta), hafnium (Hf), tungsten (W), molybdenum (Mo), zirconium (Zr), or niobium (Nb).

In some embodiments, the first electrode is fabricated on a substrate, wherein the substrate includes at least one of silicon carbide (SiC), aluminum nitride (AlN), gallium nitride (GaN), or gallium oxide (Ga₂O₃).

In some embodiments, the switching oxide includes at least one of HfOₓ, TaO_{y}, or ZrO_{z}, wherein x≤2.0, y≤2.5, z≤2.0.

In some embodiments, the first electrode material includes at least one of platinum (Pt), iridium (Ir), palladium (Pd), carbon (graphene), chromium (Cr), ruthenium (Ru), TiN, TaN, or a conductive ceramic.

In some embodiments, the conductive ceramic includes at least one of RuO₂, Bi₂Ru₂O₇, or Bi₂Ir₂O₇.

In some embodiments, the second electrode material includes W.

In some embodiments, the first electrode material includes at least one of graphene, Ru, or Cr.

In some embodiments, the RRAM device further includes a first interface layer positioned between the first electrode and the switching oxide, and wherein the first interface layer includes a first oxide that is more chemically stable than the switching oxide and an oxide of the second electrode material.

In some embodiments, the first oxide includes at least one of Al₂O₃, Y₂O₃, or MgO.

In some embodiments, the RRAM device further includes a second interface layer fabricated between the second electrode and the switching oxide layer, wherein the second interface layer includes a discontinuous film of a second oxide that is more chemically stable than the switching oxide and an oxide of the second electrode material.

In some embodiments, the second oxide includes at least one of Al₂O₃, Y₂O₃, or MgO.

In some embodiments, the RRAM device further includes a third interface layer in the switching oxide layer, wherein the third interface layer includes a third oxide that is more chemically stable than the switching oxide and the oxide of the second electrode material.

In some embodiments, the third interface layer includes a discontinuous film of the third oxide, and wherein the third oxide includes at least one of Al₂O₃, Y₂O₃, or MgO.

According to one or more aspects of the present disclosure, a method for fabricating a resistive random-access memory (RRAM) device is provided. The method includes: fabricating a first electrode including a first electrode material; fabricating a switching oxide layer including a switching oxide; and fabricating a second electrode fabricated on the switching oxide layer, wherein the first electrode material is not reactive to the switching oxide, wherein the second electrode includes a second electrode material that is reactive to the switching oxide, and wherein the second electrode material includes at least one of tantalum (Ta), hafnium (Hf), tungsten (W), molybdenum (Mo), zirconium (Zr), or niobium (Nb).

In some embodiments, fabricating the first electrode includes fabricating the first electrode on a substrate, wherein the substrate includes at least one of silicon carbide (SiC), aluminum nitride (AlN), gallium nitride (GaN), or gallium oxide (Ga₂O3).

In some embodiments, the switching oxide includes at least one of HfOₓ, TaO_{y}, or ZrO_{z}, wherein x≤2.0, y≤2.5, z≤2.0.

In some embodiments, the first electrode material includes at least one of platinum (Pt), iridium (Ir), palladium (Pd), carbon, chromium (Cr), ruthenium (Ru), TiN, TaN, or a conductive ceramic.

In some embodiments, the conductive ceramic includes at least one of RuO₂, Bi₂Ru₂O₇, or Bi₂Ir₂O₇.

In some embodiments, the second electrode material includes W, and wherein the first electrode material includes at least one of graphene, Ru, or Cr.

In some embodiments, the method further includes fabricating an interface layer on the first electrode by depositing a discontinuous layer of an oxide that is more chemically stable than the switching oxide.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIG. 1 is a schematic diagram illustrating an example of a crossbar circuit in accordance with some embodiments of the present disclosure.

FIG. 2 is a schematic diagram illustrating an example of a cross-point device in accordance with some embodiments of the present disclosure.

FIGS. 3A, 3B, 3C, and 3D illustrate cross-sectional views of structures for fabricating an RRAM device in accordance with some embodiments of the present disclosure.

FIGS. 3E and 3F illustrate RRAM devices corresponding to RRAM devices at a low resistance state (LRS) and a high resistance state (HRS), respectively.

FIGS. 4A and 4B illustrate cross-sectional views of structures relating to a process for fabricating an RRAM device in accordance with some implementations of the present disclosure.

FIG. 4C illustrates the RRAM device shown in FIG. 4B at a low resistance state in accordance with some implementations of the present disclosure.

FIG. 4D illustrates the RRAM device shown in FIG. 4C at a high resistance state in accordance with some implementations of the present disclosure.

FIG. 5 illustrates a cross-sectional view of an RRAM device in accordance with some embodiments of the present disclosure.

FIG. 6 is a schematic diagram illustrating a cross-sectional view of a switching oxide layer with an embedded interface layer in accordance with some embodiments of the present disclosure.

FIG. 7 illustrates a Ru—W binary phase diagram.

FIG. 8 illustrates a chromium-tungsten (Cr—W) binary phase diagram.

FIG. 9 is a flow diagram illustrating an example of a process for fabricating an RRAM device according to some embodiments of the disclosure.

FIG. 10 is a flow diagram illustrating an example of a process for fabricating an RRAM device according to some embodiments of the disclosure.

FIG. 11 is a flow diagram illustrating an example of a process for fabricating a switching oxide layer of an RRAM device according to some embodiments of the disclosure.

### DETAILED DESCRIPTION

Aspects of the disclosure provide resistive random-access memory (RRAM) devices for high-temperature applications and methods for fabricating the RRAM devices. An RRAM device is a two-terminal passive device with tunable resistance. The RRAM device may be in an initial state or virgin state and may have an initial high resistance before it is subject to a suitable electrical stimulation (e.g., a voltage or current signal applied to the RRAM device). The RRAM device may be tuned to a lower resistance state from the virgin state via a forming process or from a high-resistance state (HRS) to a lower resistance state (LRS) via a setting process. The forming process may refer to programming a device starting from the virgin state. The setting process may refer to programming a device starting from the high resistance state (HRS) not in the virgin state. After the reactive metal electrode is deposited on the switching oxide, the reactive metal can absorb oxygen from the switching oxide layer and create oxygen vacancies in the switching oxide layer, and oxygen ions can migrate in the switching oxide through a vacancy mechanism. During a forming process, a suitable programming signal (e.g., a voltage or current signal) may be applied to the RRAM device, which may cause a drift of oxygen ions to migrate from the switching oxide to the reactive electrode. As a result, a conductive channel or filament may form through the switching oxide layer (e.g., from the reactive electrode to the non-reactive electrode). The RRAM device may then be reset to a high-resistance state by applying a reset signal (e.g., a voltage signal, a current signal) to the RRAM device. The application of the reset signal to the RRAM device may cause oxygen to migrate back to the switching oxide layer and thus interrupt the conductive filament. The RRAM device may be electrically switched between a high-resistance state and a low-resistance state by applying suitable programming signals (e.g., voltage signals, current signals, etc.) to the RRAM device. In a crossbar array circuit, the programming signals may be provided to the designated RRAM device via a selector, such as a transistor.

Enabling RRAM devices to operate reliably under high temperature (e.g., temperatures exceeding 400 °C, 600 °C, and potentially 800 °C), high power, and high radiation conditions may be highly advantageous. This would enhance their performance for demanding applications in areas such as engine control, power systems, automotive electronics, aerospace, and communications.

In accordance with some embodiments of the present disclosure, RRAM devices configured to operate at high temperatures are provided. An RRAM device may include a first electrode, a second electrode, and a switching oxide layer positioned between the first electrode and the second electrode. The RRAM device may be fabricated on a substrate of a suitable material with high thermal stability, such as silicon carbide (SiC), aluminum nitride (AlN), gallium nitride (GaN), gallium oxide (Ga₂O₃), etc.

The switching oxide layer may include a switching oxide with high thermal stability, such as HfO₂, Ta₂O₅, ZrO₂, etc. In some embodiments, the switching oxide may be doped with one or more high-stability dopants to limit the ion migration within the switching oxide. Examples of the dopants may include Al₂O₃, AlN, SiO₂, MgO, Y₂O₃, etc.

The first electrode may include a first electrode material that is non-reactive to the switching oxide and presents high thermal stability, such as a noble metal (e.g., platinum (Pt), iridium (Ir), palladium (Pd), etc.), carbon (graphite, or graphene), chromium (Cr), ruthenium (Ru), a nitride (e.g., TiN, TaN), a conductive ceramic (e.g., RuO₂, Bi₂Ru₂O₇, Bi₂Ir₂O₇, etc.), etc. The second electrode may include a second electrode material that is reactive to the switching oxide and presents high thermal stability, such as tantalum (Ta), hafnium (Hf), tungsten (W), molybdenum (Mo), zirconium (Zr), niobium (Nb), etc.

In some embodiments, a pair of the first electrode material and the second electrode material may be selected from materials such that the migration species in the switching oxide chemically and thermodynamically do not react with the first electrode (non-reactive) or exhibit a high interface energy with the first electrode. For example, the second electrode material may be tungsten (W), and the first electrode material may be one of graphene, ruthenium (Ru), or chromium (Cr).

The RRAM device may further include a first interface layer positioned between the first electrode and the switching oxide layer, a second interface layer positioned between the switching oxide layer and the second electrode, and/or a third interface layer embedded within the switching oxide layer. Each of the first interface layer, the second interface layer, and the third interface layer may include an oxide that is more chemically stable than the switching oxide and an oxide of the second electrode material, such as Al₂O₃, Y₂O₃, MgO, etc. The first interface layer, the second interface layer, and the third interface layer may or may not contain the same oxide. The interface layers may serve critical functions in high-temperature applications by limiting the filament/electrode contact and restricting diffusion between the switching oxide and the electrodes, and by limiting the ionic migration within the switching oxide.

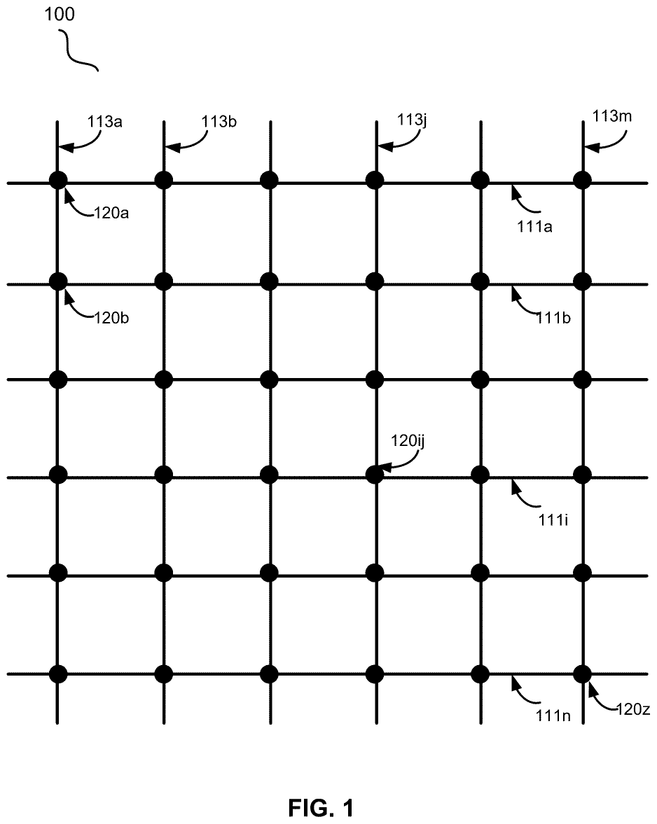

FIG. 1 is a schematic diagram illustrating an example 100 of a crossbar circuit in accordance with some embodiments of the present disclosure. As shown, crossbar circuit 100 may include a plurality of interconnected electrically conductive wires, such as one or more row wires 111a, 111b, . . . , 111i, . . . , 111n, and column wires 113a, 113b, . . . , 113j, . . . , 113m, for an n-row by m-column crossbar array. The crossbar circuit 100 may further include cross-point devices 120a, 120b, . . . , 120z, etc. Each cross-point device may connect a row wire to a column wire. For example, cross-point device 120ij may connect row wire 111i to column wire 113j.

In some embodiments, crossbar circuit 100 may further include digital-to-analog converters (DACs, not shown), analog-to-digital converters (ADCs, not shown), switches (not shown), and/or other suitable circuit components for implementing a crossbar-based apparatus. The number of column wires 113a-113m and the number of row wires 111a-111n may or may not be the same.

Row wires 111a-111n may include a first row wire 111a, a second row wire 111b, . . . , 111i, . . . , and an n-th row wire 111n. Each of row wires 111a-111n may be or may include any suitable electrically conductive material. In some embodiments, each row wire 111a-111n may be a metal wire.

Column wires 113a-113m may include a first column wire 113a, a second column wire 113b, . . . , and an m-th column wire 113m. Each of column wires 113a-113m may be or may include any suitable electrically conductive material. In some embodiments, each column wire 113a-113m may be a metal wire.

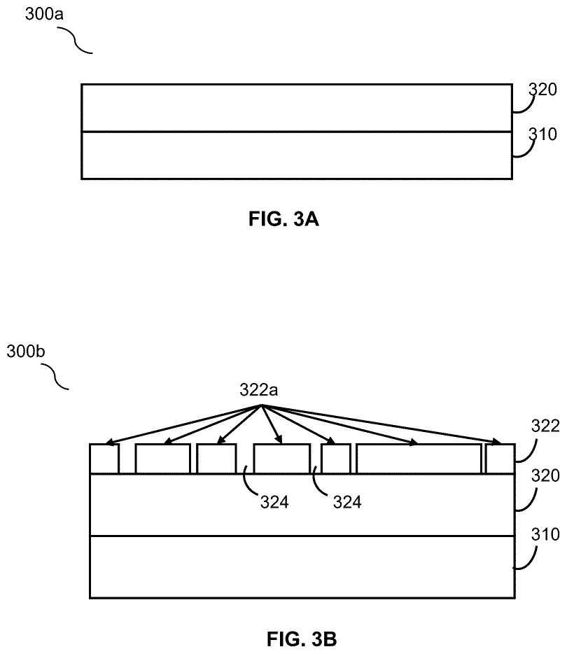

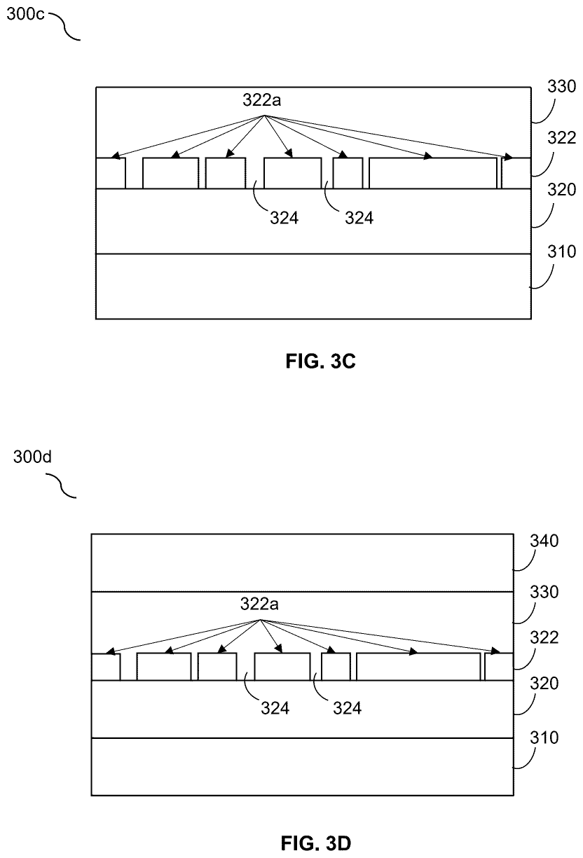

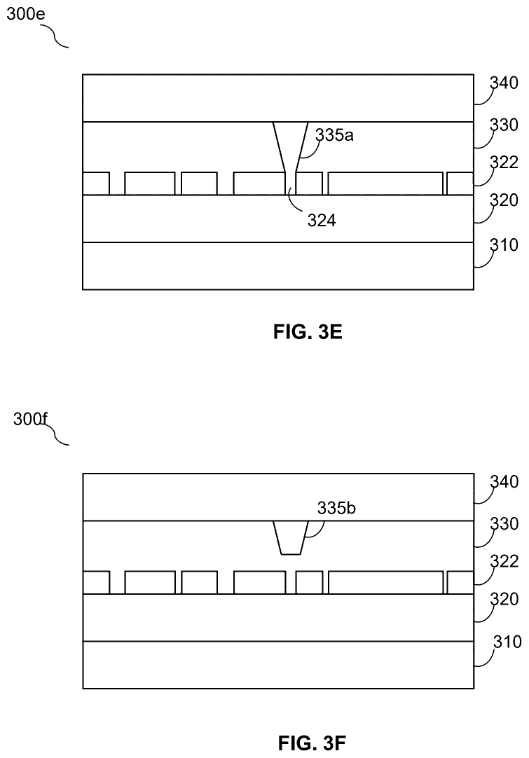

Each cross-point device 120a-120z may be or may include any suitable device with tunable resistance, such as a memristor, phase change memory (PCM) device, floating gate, spintronic device, resistive random-access memory (RRAM), magneto-resistive random-access memory (MRAM), static random-access memory (SRAM), etc. In some embodiments, one or more cross-point devices 120a-120z may include an RRAM device as described in connection with FIGS. 3A-6.

Crossbar circuit 100 may perform parallel weighted voltage multiplication and current summation. For example, an input voltage signal may be applied to one or more rows of crossbar circuit 100 (e.g., one or more selected rows). The input signal may flow through the cross-point devices along the selected rows. The conductance of each cross-point device may be tuned to a specific value (also referred to as a “weight”).

According to Ohm's law, the input voltage multiplies the conductance of each cross-point device to generate a corresponding current. According to Kirchhoff's current law, the currents passing through the devices in each column are summed to produce an output signal, which may be read from the column wires (e.g., outputs of the ADCs).

The input-output relationship of the crossbar array can be represented as I=VG, where I represents the output signal matrix as current, V represents the input signal matrix as voltage, and G represents the conductance matrix of the cross-point devices. Accordingly, the input signal is weighted at each cross-point device by its conductance (Ohm's law), and the resulting weighted currents are accumulated along the columns (Kirchhoff's law). This operation enables in-memory computing (IMC) through parallel multiplication and summation performed directly in the crossbar array.

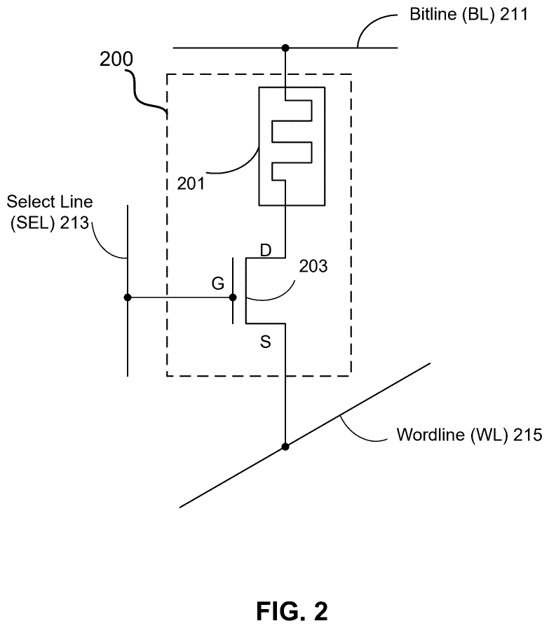

FIG. 2 is a schematic diagram illustrating an example 200 of a cross-point device in accordance with some embodiments of the present disclosure. As shown, cross-point device 200 may connect a bitline (BL) 211, a select line (SEL) 213, and a wordline (WL) 215. The bitline 211 and the wordline 215 may correspond to a column wire and a row wire, respectively, as described in connection with FIG. 1.

Cross-point device 200 may include an RRAM device 201 and a transistor 203. A transistor may include three terminals, which may be marked as gate (G), source(S), and drain (D), respectively. The transistor 203 may be connected in series with RRAM device 201. As shown in FIG. 2, the first electrode of the RRAM device 201 may be connected to the drain of transistor 203. The second electrode of the RRAM device 201 may be connected to the bitline 211. The source of the transistor 203 may be connected to the wordline 215. The gate of the transistor 203 may be connected to the select line 213. RRAM device 201 may include one or more RRAM devices as described in connection with FIGS. 3A-6 below. Cross-point device 200 may also be referred to as a one-transistor-one-resistor (1T1R) configuration. The transistor 203 may function as a selector as well as a current controller, which may set the current compliance to the RRAM device 201 during programming. The gate voltage on transistor 203 can set the current compliance to cross-point device 200 during programming, thereby controlling the conductance and analog behavior of cross-point device 200. For example, when cross-point device 200 is set from a high-resistance state to a low-resistance state, a set signal (e.g., a voltage signal, a current signal) may be provided via the bitline (BL) 211. Another voltage, also referred to as a select voltage or gate voltage, may be applied via the select line (SEL) 213 to the transistor gate to turn on the gate and set the current compliance, while the wordline (WL) 215 may be set to ground. When cross-point device 200 is reset from the low-resistance state to the high-resistance state, a gate voltage may be applied to the gate of the transistor 203 via the select line 213 to turn on the transistor gate. Meanwhile, a reset signal may be applied to the RRAM device 201 via the wordline 215, while the bitline 211 may be set to ground.

FIGS. 3A, 3B, 3C, and 3D illustrate cross-sectional views of structures 300a, 300b, 300c, and 300d for fabricating an RRAM device in accordance with some embodiments of the present disclosure. FIGS. 3E and 3F illustrate RRAM devices 300e and 300f corresponding to RRAM devices 300c-d at a low resistance state (LRS) and a high resistance state (HRS), respectively.

As shown in FIG. 3A, a substrate 310 may be provided. A first electrode 320 may be fabricated on the substrate 310. The substrate 310 may include one or more layers of any suitable material that can serve as a substrate for an RRAM device and present high thermal stability, such as silicon carbide (SiC), aluminum nitride (AlN), gallium nitride (GaN), gallium oxide (Ga₂O₃), etc. In some embodiments, the substrate 310 may include diodes, transistors, interconnects, integrated circuits, or one or more other RRAM devices. In some embodiments, the substrate 310 may include a driving circuit comprising one or more electrical circuits (e.g., an array of electrical circuits) that may be individually controllable. In some embodiments, the driving circuit may include one or more complementary metal-oxide-semiconductor (CMOS) drivers.

The first electrode 320 may include one or more electrode materials that are electronically conductive and non-reactive to the switching oxide layer to be fabricated on the first electrode 320 (also referred to as the “first electrode material”). There is no ionic exchange between the first electrode 320 and the switching oxide layer. The first electrode materials may have suitable melting points for implementing RRAM devices in high-temperature applications. For example, the first electrode materials may be a noble metal, such as Pt (with a melting point of 1768 °C), Pd (with a melting point of 1555 °C), Ir (with a melting point of 2446 °C), etc. As another example, the first electrode material may include a nitride with a suitable melting point, such as TiN (with a melting point of 2930 °C), TaN (with a melting point of 3400 °C), etc. As a further example, the first electrode material may include carbon, such as graphene (with a sublimation point of 3652-3697 °C). As still another example, the first electrode material may include a conductive ceramic, such as RuO₂ (with a melting point of 1200 °C), bismuth ruthenate (Bi₂Ru₂O₇) (with a melting point of 1500 °C), bismuth iridate (Bi₂Ir₂O₇), etc. The first electrode 320 may also be referred to as the “non-reactive electrode.”

As shown in FIG. 3B, an interface layer 322 (also referred to as the “first interface layer”) may be fabricated on the first electrode 320. The interface layer 322 may be and/or include a discontinuous film 322a of a first oxide that is more chemically stable than the switching oxide(s) in the switching oxide layer and the electrode material in the second electrode to be fabricated on the interface layer 322. As a result, the oxide may not react with the switching oxide(s) in the switching oxide layer or the second electrode. As an example, the first oxide may include Al₂O₃, Y₂O₃, MgO, etc.

As shown, the discontinuous film 322a may include pores and/or pin-holes 324 that are randomly dispersed in the interface layer 322. While a certain number of pores are illustrated in FIG. 3B, this is merely illustrative. The discontinuous film 322a may include any suitable number of pores and/or pin-holes. In some embodiments, a thickness of the interface layer 322 and/or the discontinuous film 322 a may be between about 0.2 nm and about 0.5 nm. In some embodiments, the discontinuous film 322a may be an Al₂O₃ film having a thickness equal to or less than 0.5 nm. In some embodiments, the discontinuous film 322 a may be and/or include an Al₂O₃ film having a thickness of less than 1 nm.

As referred to herein, a layer may be regarded as being a discontinuous layer if the layer covers some, but not all, portions of the layer underneath. A discontinuous layer of the first oxide may be fabricated by depositing the first oxide to form a layer that is not thick enough to form a continuous layer of the first oxide. In some embodiments, the thickness of the first interface layer and/or the discontinuous film of the oxide may be approximately of the order of magnitude of the diameter of a single atom or molecule of the first oxide. In some embodiments, a thickness of the interface layer 322 may be between about 0.2 nm and about 0.5 nm. In some embodiments, a thickness of the interface layer 322 may be about 0.3 nm. As a more particular example, the thickness of an Al₂O₃ monolayer is estimated to be more than the diameter of an Al ion plus the diameter of an oxygen ion, where the diameter of an oxygen ion is 0.252 nm; the diameter of an Al³⁺ ionic is 0.136 nm; and the size of an AlO ion pair is 0.388 nm. As such, an Al₂O₃ layer may be discontinuous when the thickness of the Al₂O₃ film is less than about 0.4 nm. As another more particular example, the diameter of a Si⁴⁺ ion is 0.108 nm; the size of an Si-0 ionic pair is 0.360 nm. Thus, a complete SiO2 monolayer is often not formed, if the thickness of a deposited SiO₂ layer is less than 0.4 nm. In some embodiments, even when the thickness of a deposited film is thicker than 0.4 nm, a dielectric film may still be non-continuous due to the surface energy (or wettability) between the dielectric film and the first electrode.

Referring to FIG. 3C, a switching oxide layer 330 may be deposited on the interface layer 322. The switching oxide layer 330 may include one or more switching oxides (e.g., transition metal oxides) with high thermal stability for fabricating RRAM devices for high-temperature applications. Examples of the switching oxides include HfOx (e.g., HfO₂ with a melting point of 2758 °C, where x represents the stoichiometric ratio and x≤2), TaOy (e.g., Ta₂O₅ with a melting point of 1872 °C, where y represents the stoichiometric ratio and y≤2.5), zirconium oxide (ZrO_{z}) (with a melting point of 2715 °C, where z represents the stoichiometric ratio and z≤2), etc.

In some embodiments, switching oxide layer 330 may include one or more of the switching oxides doped with high stability dopants, which may further limit the ion migration within the switching oxide layer 330. Examples of the dopants may include Al₂O₃, AlN, SiO₂, MgO, Y₂O₃, etc.

In some embodiments, switching oxide layer 330 may include an interface layer comprising one or more oxides that are more chemically stable than the switching oxide. For example, switching oxide layer 300 may include a switching oxide layer 600 of FIG. 6.

In some embodiments, the chemical stability of the first electrode material in the first electrode 320 may be higher than that of the switching oxide(s) in the switching oxide layer 330.

As shown in FIG. 3D, a second electrode 340 may be fabricated on the switching oxide layer 330 to fabricate an RRAM device 300a. The second electrode 340 may include a suitable electrode material that is electronically conductive and reactive to the switching oxide(s) in the switching oxide layer 330 (also referred to as the “second electrode material”). The second electrode material may have suitable thermal stability for fabricating RRAM devices for high-temperature applications. For example, the second electrode material may be Ta (with a melting point of 3020 °C), Hf (with a melting point of 2227 °C), W (with a melting point of 3422 °C), Mo (with a melting point of 2623 °C), Zr (with a melting point of 1855 °C), Nb (with a melting point of 2477 °C), etc.

The second electrode 340 may be reactive to the switching oxide(s) in the switching oxide layer 330 and may have suitable oxygen solubility to adsorb some oxygen from the switching oxide layer 330 and create oxygen vacancies in the switching oxide layer 330. In other words, the reactive electrode material(s) in the second electrode 340 may have suitable oxygen solubility and/or oxygen mobility. In some embodiments, the second electrode 340 may not only be able to create oxygen vacancies in the switching oxide layer 330 (e.g., by scavenging oxygen), but also may function as an oxygen reservoir or source to the switching oxide layer 330 during cell programming. In some embodiments, the second electrode may provide metal ions (cations) that may migrate into the switching oxide layer 330.

In some embodiments, particular pairs of first electrode materials and second electrode materials may be used to implement the first electrode 320 and the second electrode 340 so that the migration species in the switching oxide chemically and thermodynamically do not react with the first electrode (non-reactive), or have a high interface energy that discourages contact with the first electrode. For example, the first electrode material and the second electrode material may be graphene (Gr) and tungsten (W), respectively, due to the high contact resistance and poor adhesion between W and Gr. Poor adhesion could result in poor wetting: the high surface energy of W can lead to inadequate wetting on the Gr substrate, preventing W from spreading and forming a good interface with Gr. This could be beneficial for high-temperature RRAM applications, where, when W contacts the Gr surface, W would not form a strong interface with Gr, limiting the bonding of W to the Gr surface, reducing the diffusion of W into Gr, and thereby extending the life of the RRAM at high temperatures.

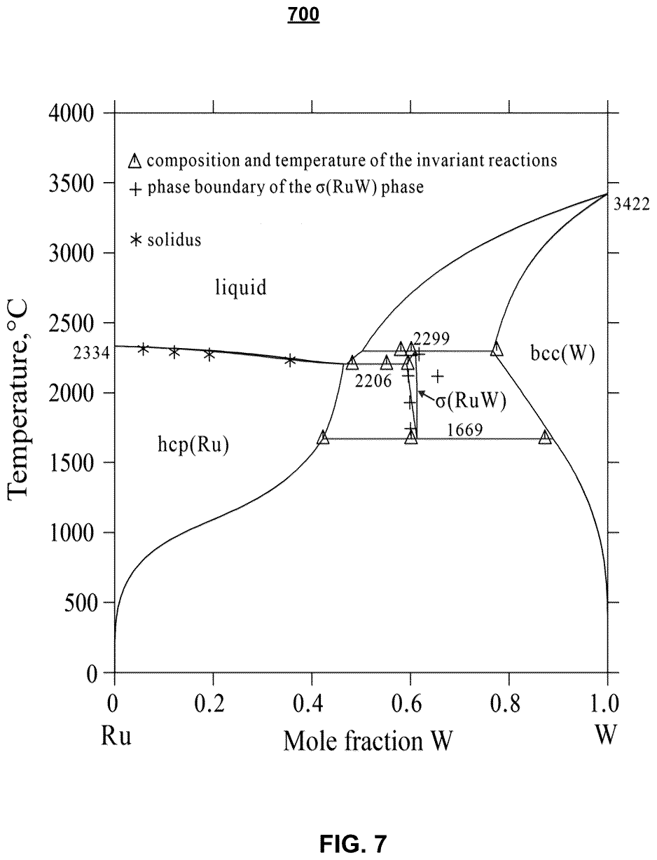

As another example, the first electrode material and the second electrode material may be ruthenium (Ru) and tungsten (W), respectively. The Ru—W phase diagram as shown in FIG. 7 indicates that W and Ru phases are immiscible at room temperature, with very low solubility at approximately 500 °C. This suggests that, if Ru is the migrating species, the migration of Ru into the W electrode will be less likely from a thermodynamic perspective. Conversely, if W is the migrating species, the migration of W into the Ru electrode will be limited by thermodynamics.

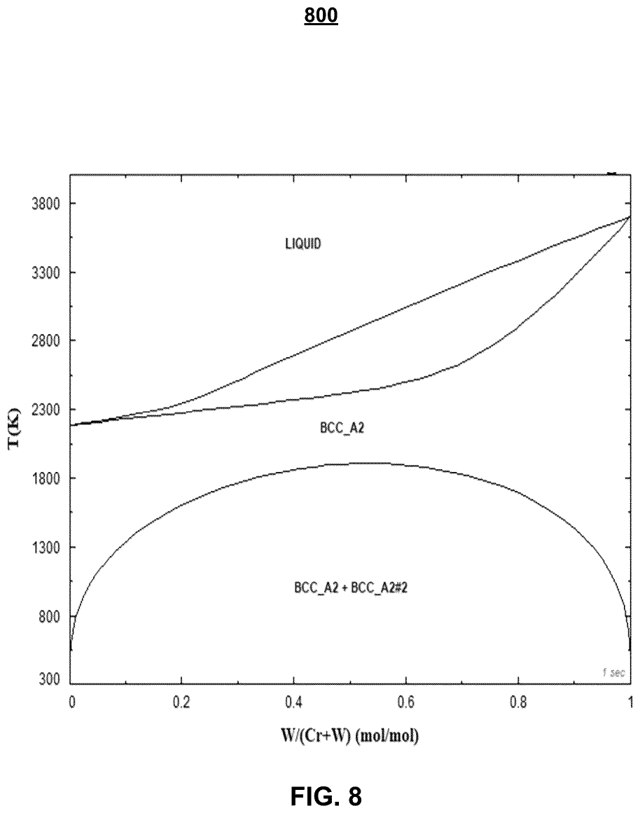

As a further example, the first electrode material and the second electrode material may be chromium (Cr) and tungsten (W), respectively. The Cr—W phase diagram shown in FIG. 8 shows a wide miscibility gap, which refers to a range of compositions where a mixture of substances is not completely miscible and exists or separates as distinct phases, such as Cr-rich and W-rich phases. This suggests that when W contacts the Cr surface, W will not mix with Cr. Instead, W will remain separate from Cr. This indicates that the migration of W into the Cr electrode will be limited by thermodynamics.

FIGS. 3E and 3F illustrate RRAM devices 300e and 300f corresponding to a low-resistance state and a high-resistance state of RRAM device 300d, respectively. The incorporation of the interface layer 322 may reduce the contact area between the switching oxide layer 330 and the first electrode 320. As illustrated in FIG. 3E, a conductive channel 335a may be formed from the second electrode 340 to the first electrode 320 through the interface layer 322 and the switching oxide layer 330. As illustrated in FIG. 3F, an interrupted conductive channel 335b may be formed in the switching oxide layer 330 during the reset process. The incorporation of the interface layer 422 into the RRAM device may enable high-temperature applications by limiting the filament/electrode contact and restricting diffusion between the switching oxide and the electrodes.

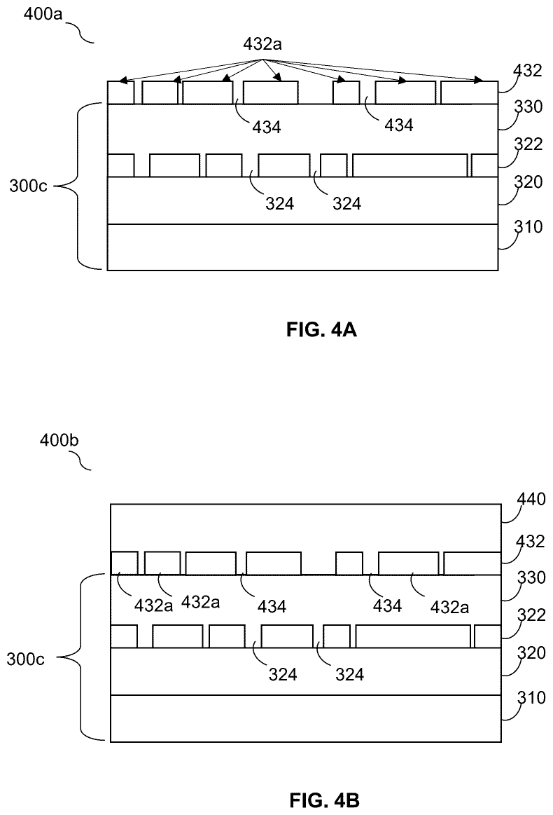

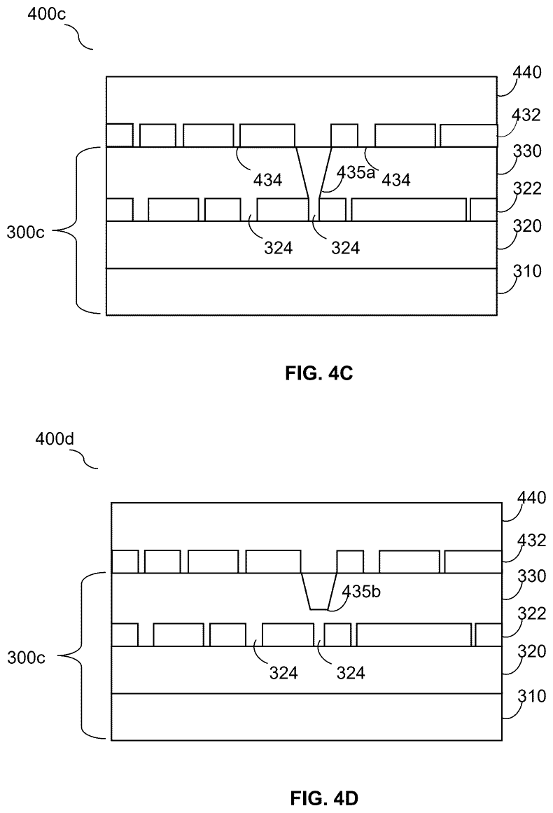

FIGS. 4A and 4B are schematic diagrams illustrating structures relating to a process for fabricating an RRAM device in accordance with some implementations of the present disclosure.

In some embodiments, an RRAM device may include multiple interface layers fabricated between the first electrode and the second electrode. Each of the interface layers may include a discontinuous film as described in connection with FIG. 3B. For example, as illustrated in FIG. 4A, a semiconductor device 400a may be fabricated by fabricating an interface layer 432 (also referred to as the “second interface layer”) on the structure 300c as described in connection with FIG. 3C. In some embodiments, the second interface layer 432 may include a discontinuous film 432a of a second oxide. The second oxide may be more chemically stable than the transition metal oxide in the switching oxide layer 330 and the second electrode material in the second electrode. As an example, the second oxide may include Al₂O₃, MgO, Y₂O₃, etc. The second oxide may or may not be the same as the first oxide.

The discontinuous film 432a may include one or more pores and/or pin-holes 434 (also referred to as the “one or more second pores and/or pin-holes”). The pore(s) 434 may have any suitable size and/or dimension. Multiple pores 434 may or may not have the same size and/or dimension. In some embodiments, the second interface layer 432 and/or the second discontinuous film 432a may include multiple pores 434 dispersed randomly on the second interface layer 432. The discontinuous film 432a may include any suitable number of pores and/or pin-holes.

In some embodiments, a thickness of the second interface layer 432 and/or the second discontinuous film (also referred to as the “second thickness”) may be between about 0.2 nm and about 0.5 nm. As another example, the second interface layer 432 may include a discontinuous Al₂O₃ film having a thickness equal to or less than 0.5 nm. In some embodiments, the second interface layer 432 may include a discontinuous Al₂O₃ film having a thickness less than 1 nm. The second thickness of the second interface layer 432 may or may not be the same as the first thickness of the first interface layer 422.

As illustrated in FIG. 4B, a second electrode 440 may be fabricated on the second interface layer 432 to fabricate an RRAM device 400b. The second interface layer 432 is positioned between the switching oxide layer 330 and the second electrode 440. The second electrode 440 may be and/or include the second electrode 340 as described in conjunction with FIG. 3D. In some embodiments, during the fabrication of the second electrode 440, one or more portions of the second electrode 440 may be deposited on the switching oxide layer 330 through one or more pores and/or pin-holes 434. That is, at least some of the second electrode material in the second electrode 440 is deposited on the switching oxide layer 330 through pores and/or pin-holes 434. As such, the second electrode 440 may directly contact one or more portions of the switching oxide layer 330 through one or more pores/pin-holes 434.

FIGS. 4C and 4D illustrate semiconductor devices 400c and 400d that may correspond to a low-resistance state and a high-resistance state of the RRAM device 400b, respectively. The incorporation of both the first interface layer 322 and the second interface layer 432 may further reduce the contact area between the switching oxide layer 330 and the first electrode 320 and the contact area between the switching oxide layer 330 and the second electrode 440. As illustrated in FIG. 4C, a conductive channel 435a may be formed from the second electrode 440 to the first electrode 320 through the second interface layer 432, the switching oxide layer 330, and the first interface layer 322. As illustrated in FIG. 4D, an interrupted conductive channel 435b may be formed in the switching oxide layer 330 during the reset process.

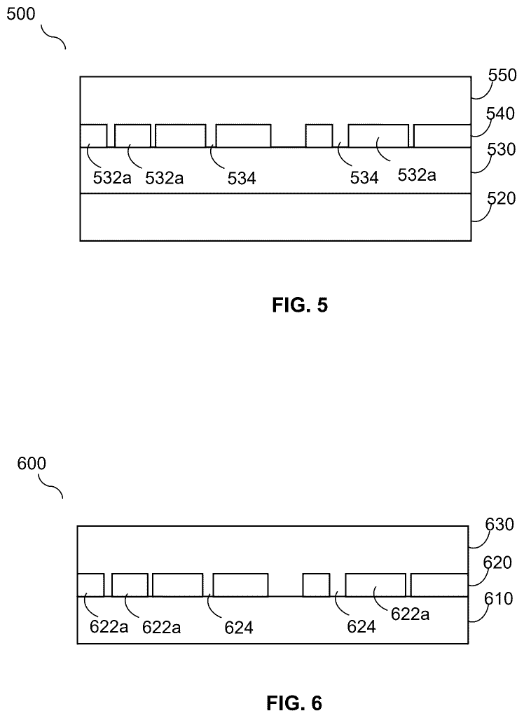

In some embodiments, the first interface layer or the second interface layer may be omitted from the RRAM device. For example, as shown in FIG. 5, an RRAM device 500 may include a first electrode 520, a switching oxide layer 530, an interface layer 540, and a second electrode 550. The first electrode 520 may be the same as the first electrode 320.

The switching oxide layer 530 may include one or more switching oxides (e.g., transition metal oxides) with high thermal stability for fabricating RRAM devices for high-temperature applications. Examples of the switching oxides include HfOx (e.g., HfO₂ with a melting point of 2758 °C, where x represents the stoichiometric ratio and x≤2.0), TaOy (e.g., Ta₂O₅ with a melting point of 1872 °C, where y represents the stoichiometric ratio and y≤2.5), zirconium oxide (ZrO_{z}) (with a melting point of 2715 °C, where z represents the stoichiometric ratio and z≤2.0), etc.

In some embodiments, switching oxide layer 530 may include one or more of the switching oxides doped with high stability dopants, which may further limit the ion migration within the switching oxide layer 330. Examples of the dopants may include Al₂O₃, AlN, SiO₂, MgO, Y₂O₃, etc.

In some embodiments, switching oxide layer 530 may include an interface layer comprising one or more oxides that are more chemically stable than the switching oxide. For example, switching oxide layer 300 may include a switching oxide layer 600 of FIG. 6.

The interface layer 540 may be the same as the interface layer 432 of FIG. 4A. In some embodiments, the interface layer 540 may include a discontinuous film 532a of an oxide. The oxide may be more chemically stable than the transition metal oxide in the switching oxide layer 530 and the second electrode material in the second electrode. As an example, the oxide may include Al₂O₃, MgO, Y₂O₃, etc. The discontinuous film 532a may include one or more pores and/or pin-holes 534. The pore(s) 534 may have any suitable size and/or dimension. Multiple pores 534 may or may not have the same size and/or dimension. In some embodiments, the second interface layer 540 and/or the second discontinuous film 532a may include multiple pores 534 dispersed randomly on the second interface layer 530. The discontinuous film 532a may include any suitable number of pores and/or pin-holes.

The second electrode 550 may be the same as the second electrode 440 of FIG. 4B.

FIG. 6 is a schematic diagram illustrating a cross-sectional view of a switching oxide layer 600 incorporating an interface layer in accordance with some embodiments of the present disclosure.

As shown, switching oxide layer 600 may include an interface layer 620 fabricated between a first switching oxide sublayer 610 and a second switching oxide sublayer 630. Each of the first switching oxide sublayer 610 and the second switching oxide sublayer 630 may include one or more first switching oxides (e.g., transition metal oxides) with high thermal stability for fabricating RRAM devices for high-temperature applications. Examples of the switching oxides include HfOx (e.g., HfO₂ with a melting point of 2758 °C, where x represents the stoichiometric ratio), TaOy (e.g., Ta₂O₅ with a melting point of 1872 °C, where y represents the stoichiometric ratio), zirconium oxide (ZrO₂) (with a melting point of 2715 °C), etc. In some embodiments, the first switching oxide sublayer 610 and/or the second switching oxide sublayer 630 may include one or more of the switching oxides doped with high stability dopants, which may further limit the ion migration within the switching oxide layer 600. Examples of the dopants may include Al₂O₃, AlN, SiO₂, MgO, Y₂O₃, etc.

The interface layer 620 (also referred to as the “third interface layer”) may include an oxide (also referred to as the “third oxide”) that is more chemically stable than the switching oxide(s) of the switching oxide layer described subsequently. Examples of the first oxide may include Al₂O₃, Y₂O₃, MgO, etc. In some embodiments, the interface layer 620 may include a discontinuous film 622a of the third oxide. The discontinuous film 622a may include pores and/or pin-holes 624 that are randomly dispersed in the interface layer 620. While a certain number of pores are illustrated in FIG. 6, this is merely illustrative. The discontinuous film 622a may include any suitable number of pores and/or pin-holes. In some embodiments, a thickness of the interface layer 620 and/or the discontinuous film 622a may be between about 0.2 nm and about 0.5 nm. In some embodiments, the discontinuous film 622 a may be an Al₂O₃ film having a thickness equal to or less than 0.5 nm. In some embodiments, the discontinuous film 622 a may be and/or include an Al₂O₃ film having a thickness of less than 1 nm. Although the switching oxide 600 in FIG. 6 shows one interface layer 620 between two switching oxide sublayers 610 and 630, the switching oxide 600 may include additional interface layers 620 between additional switching oxide sublayers (not shown).

FIG. 7 illustrates a Ru-W binary phase diagram 700. which shows that ruthenium and tungsten are essentially immiscible at room temperature and exhibit only very low mutual solubility at temperatures up to about 500 °C. Accordingly, when ruthenium is the migrating species, diffusion of Ru into a tungsten electrode may be thermodynamically unfavorable. Conversely, when tungsten is the migrating species, diffusion of W into a ruthenium electrode may likewise be thermodynamically limited.

FIG. 8 illustrates a chromium-tungsten (Cr—W) binary phase diagram 800. Diagram 800 shows a wide miscibility gap in which the alloy separates into Cr-rich and W-rich phases rather than forming a single homogeneous solid solution. Consequently, when tungsten comes into contact with a chromium surface, tungsten is thermodynamically disinclined to dis-solve into the chromium matrix and instead tends to remain segregated. Thus, migration of W into a Cr electrode is expected to be severely limited by thermodynamic considerations.

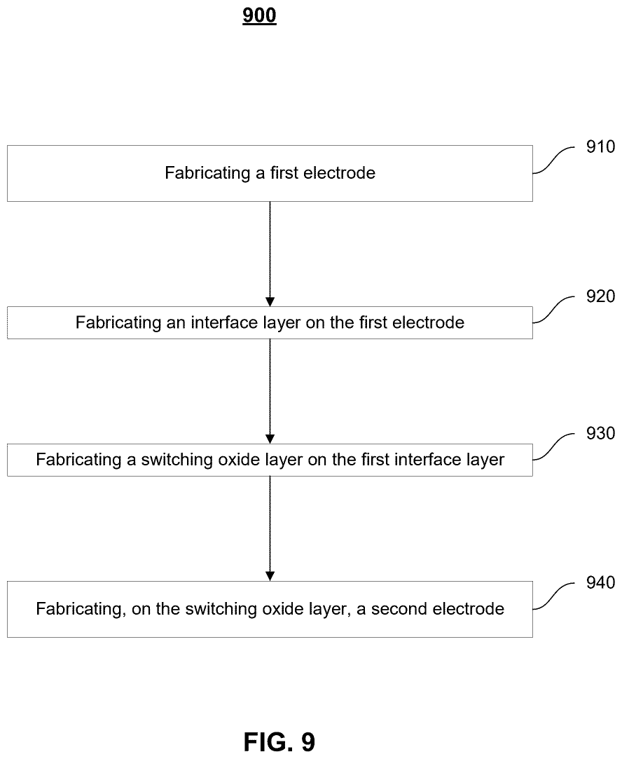

FIG. 9 is a flow diagram illustrating an example 900 of a process for fabricating an RRAM device according to some embodiments of the disclosure, including RRAM device 300d in FIG. 3D.

At block 910, a first electrode may be fabricated on a substrate. The substrate comprises at least one of silicon carbide (SiC), aluminum nitride (AlN), gallium nitride (GaN), or gallium oxide (Ga₂O₃) as described in 310 in connection with FIG. 3A above. Fabricating the first electrode may involve depositing a first electrode material that is electronically conductive and non-reactive to the switching oxide layer to be fabricated on the first electrode. The first electrode materials may have suitable thermal stability for implementing RRAM devices in high-temperature applications, such as Pt, Pd, Ir, TiN, TaN, carbon (e.g., graphene), a conductive ceramic (e.g., RuO₂, Bi₂Ru₂O₇, Bi₂Ir₂O₇, etc.). The first electrode material may be deposited, for example, using physical vapor deposition (PVA), chemical vapor deposition (CVD), atomic layer deposition (ALD), or any other suitable deposition techniques. The first electrode may be and/or include first electrode 320 as described in connection with FIG. 3D above.

At block 920, an interface layer may be fabricated on the first electrode. The interface layer may include an oxide that is more chemically stable than the switching oxide(s) of the switching oxide layer described subsequently. Examples of the oxide may include Al₂O₃, Y₂O₃, MgO, etc. For example, fabricating the first interface layer may involve depositing AlOₓ, utilizing an ALD technique, a PVD technique, a reactive sputtering of Al technique, and/or any other suitable deposition technique. Y₂O₃ and MgO may be deposited using pulsed-laser deposition (PLD), RF or DC magnetron sputtering with Y₂O₃ or MgO targets, electron-beam evaporation, molecular-beam epitaxy (MBE), chemical solution deposition or sol-gel spin-coating followed by thermal annealing, and atomic layer deposition (ALD) processes employing yttrium-or magnesium-containing precursors. In some embodiments, the interface layer may also be fabricated as a discontinuous layer of the oxide by depositing the oxide using one or more of the aforementioned techniques to a thickness insufficient to form a continuous layer thereof. The interface layer may be and/or include the interface layer 322 as described in connection with FIG. 3D above.

At block 930, a switching oxide layer may be fabricated on the interface layer. The switching oxide layer may include one or more switching oxides (e.g., transition metal oxides) with high thermal stability for fabricating RRAM devices for high-temperature applications. Examples of the switching oxides include HfOx (e.g., HfO₂, where x represents the stoichiometric ratio), TaO_{y} (e.g., Ta₂O₅, where y represents the stoichiometric ratio), zirconium oxide (ZrO₂) (with a melting point of 2715 °C), etc. For example, fabricating the switching oxide layer may involve depositing HfOₓ, utilizing an ALD technique, a PVD technique, a reactive sputtering of Hf technique, and/or any other suitable deposition technique. The switching oxide layer may be and/or include switching oxide layer 330 as described in connection with FIG. 3D above.

At block 940, a second electrode may be fabricated on the switching oxide layer. Fabricating the second electrode may involve depositing a second electrode material that is electronically conductive and reactive to the switching oxide(s) in the switching oxide layer. The second electrode material may have suitable thermal stability for fabricating RRAM devices for high-temperature applications. For example, the second electrode material may be Ta, Hf, W, Mo, Zr, Nb, etc. Fabricating the second electrode may involve depositing the selected metal using a PVD process (e.g., DC or RF magnetron sputtering, ion-beam sputtering, collimated sputtering, electron-beam evaporation, etc.), a CVD process, a molecular-beam epitaxy (MBE) process, etc. The second electrode may be and/or include second electrode 340 as described in connection with FIG. 3D above.

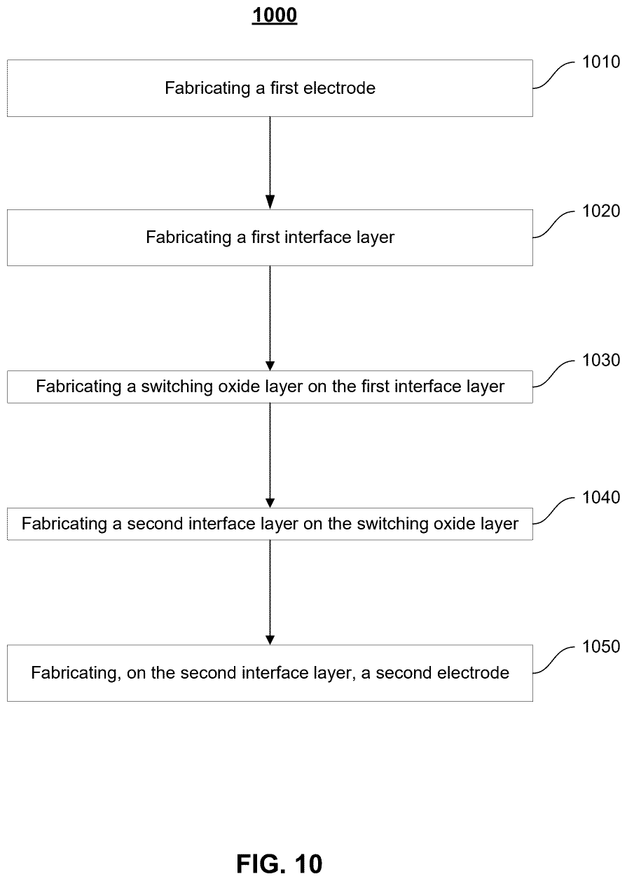

FIG. 10 is a flow diagram illustrating an example 1000 of a process for fabricating an RRAM device according to some embodiments of the disclosure, including RRAM device 400b in FIG. 4B.

At block 1010, a first electrode may be fabricated on a substrate. Fabricating the first electrode may involve depositing a first electrode material that is electronically conductive and non-reactive to the switching oxide layer to be fabricated on the first electrode. The first electrode materials may have suitable thermal stability for implementing RRAM devices in high-temperature applications, such as Pt, Pd, Ir, TiN, TaN, carbon (e.g., graphene), a conductive ceramic (e.g., RuO₂, Bi₂Ru₂O₇, Bi₂Ir₂O₇, etc.). The first electrode material may be deposited, for example, using physical vapor deposition (PVD), chemical vapor deposition (CVD), atomic layer deposition (ALD), or any other suitable deposition techniques. The first electrode may be and/or include first electrode 320 as described in connection with FIG. 4B above.

At block 1020, a first interface layer may be fabricated on the first electrode. The interface layer may include a first oxide that is more chemically stable than the switching oxide(s) of the switching oxide layer described subsequently. Examples of the first oxide may include Al₂O₃, Y₂O₃, MgO, etc. For example, fabricating the first interface layer may involve depositing AlOₓ, utilizing an ALD technique, a PVD technique, a reactive sputtering of Al technique, and/or any other suitable deposition technique. Y₂O₃ and MgO may be deposited using pulsed-laser deposition (PLD), RF or DC magnetron sputtering with Y₂O₃ or MgO targets, electron-beam evaporation, molecular-beam epitaxy (MBE), chemical solution deposition or sol-gel spin-coating followed by thermal annealing, and atomic layer deposition (ALD) processes employing yttrium-or magnesium-containing precursors. In some embodiments, the interface layer may also be fabricated as a discontinuous layer of the first oxide by depositing the first oxide using one or more of the aforementioned techniques to a thickness insufficient to form a continuous layer thereof. The first interface layer may be and/or include the interface layer 322 as described in connection with FIG. 4B above.

At block 1030, a switching oxide layer may be fabricated on the interface layer. The switching oxide layer may include one or more switching oxides (e.g., transition metal oxides) with high thermal stability for fabricating RRAM devices for high-temperature applications. Examples of the switching oxides include HfOx (e.g., HfO₂, where x represents the stoichiometric ratio), TaOy (e.g., Ta₂O₅, where y represents the stoichiometric ratio), zirconium oxide (ZrO₂) (with a melting point of 2715 °C), etc. For example, fabricating the switching oxide layer may involve depositing HfOₓ, utilizing an ALD technique, a PVD technique, a reactive sputtering of Hf technique, and/or any other suitable deposition technique. The switching oxide layer may be and/or include switching oxide layer 330 as described in connection with FIG. 4B above.

At block 1040, a second interface layer may be fabricated on the switching oxide layer. The second interface layer may include a second oxide that is more chemically stable than the switching oxide(s) of the switching oxide layer described subsequently. Examples of the second oxide may include Al₂O₃, Y₂O₃, MgO, etc. For example, fabricating the second interface layer may involve depositing AlOₓ, utilizing an ALD technique, a PVD technique, a reactive sputtering of Al technique, and/or any other suitable deposition technique. Y₂O₃ and MgO may be deposited using pulsed-laser deposition (PLD), RF or DC magnetron sputtering with Y₂O₃ or MgO targets, electron-beam evaporation, molecular-beam epitaxy (MBE), chemical solution deposition, or sol-gel spin-coating followed by thermal annealing, and atomic layer deposition (ALD) processes employing yttrium-or magnesium-containing precursors. In some embodiments, the second interface layer may also be fabricated as a discontinuous layer of the second oxide by depositing the second oxide using one or more of the aforementioned techniques to a thickness insufficient to form a continuous layer thereof. The second interface layer may be and/or include the interface layer 432 as described in connection with FIG. 4B above.

At block 1050, a second electrode may be fabricated on the second interface layer. Fabricating the second electrode may involve depositing a second electrode material that is electronically conductive and reactive to the switching oxide(s) in the switching oxide layer. The second electrode material may have suitable thermal stability for fabricating RRAM devices for high-temperature applications. For example, the second electrode material may be Ta, Hf, W, Mo, Zr, Nb, etc. Fabricating the second electrode may involve depositing the selected metal using a PVD process (e.g., DC or RF magnetron sputtering, ion-beam sputtering, collimated sputtering, electron-beam evaporation, etc.), a CVD process, a molecular-beam epitaxy (MBE) process, etc. In some embodiments in which the second interface layer includes a discontinuous film of the second oxide, one or more portions of the second electrode material may be directly deposited on the switching oxide layer through the pin-holes and/or holes of the discontinuous film of the second oxide. The second electrode may be and/or include second electrode 440 as described in connection with FIG. 4B above.

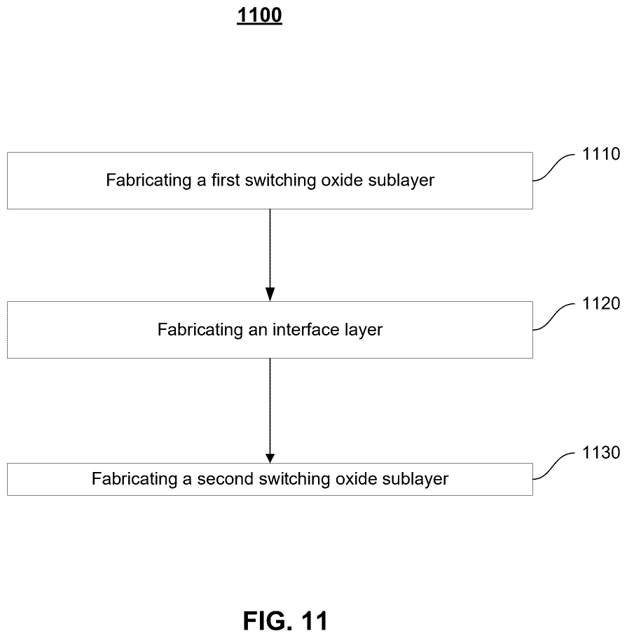

FIG. 11 is a flow diagram illustrating an example 1100 of a process for fabricating a switching oxide layer with an embedded interface layer according to some embodiments of the disclosure.

At block 1110, a first switching oxide sublayer may be fabricated. The first switching oxide sublayer may be fabricated on a first electrode and/or an interface layer as described herein. The first switching oxide layer may include one or more first switching oxides (e.g., transition metal oxides) with high thermal stability for fabricating RRAM devices for high-temperature applications. Examples of the switching oxides include HfOx (e.g., HfO₂, where x represents the stoichiometric ratio), TaO_{y} (e.g., Ta₂O₅, where y represents the stoichiometric ratio), zirconium oxide (ZrO_{z}) (with a melting point of 2715 °C), where x≤2.0, y≤2.5, z≤2.0, etc. For example, fabricating the first switching oxide sublayer may involve depositing HfOₓ, utilizing an ALD technique, a PVD technique, a reactive sputtering of Hf technique, and/or any other suitable deposition technique.

At 1120, an interface layer (the third interface layer) may be fabricated on the first switching oxide sublayer. The third interface layer may include a third oxide that is more chemically stable than the switching oxide(s) in the first switching oxide sublayer and the second switching oxide sublayer. Examples of the third oxide may include Al₂O₃, Y₂O₃, MgO, etc. For example, fabricating the third interface layer may involve depositing AlOₓ, utilizing an ALD technique, a PVD technique, a reactive sputtering of Al technique, and/or any other suitable deposition technique. Y₂O₃ and MgO may be deposited using PLD, RF or DC magnetron sputtering with Y₂O₃ or MgO targets, MBE, chemical solution deposition, or sol-gel spin-coating followed by thermal annealing, and ALD processes employing yttrium- or magnesium-containing precursors. In some embodiments, the third interface layer may also be fabricated as a discontinuous layer of the third oxide by depositing the second oxide using one or more of the aforementioned techniques to a thickness insufficient to form a continuous layer thereof.

At 1130, a second switching oxide sublayer may be fabricated on the interface layer. The second switching oxide sublayer may include one or more second switching oxides (e.g., transition metal oxides) with high thermal stability for fabricating RRAM devices for high-temperature applications. Examples of the switching oxides include HfOx, TaO_{y}, ZrO₂, etc. For example, fabricating the switching oxide layer may involve depositing HfOₓ, utilizing an ALD technique, a PVD technique, a reactive sputtering of Hf technique, and/or any other suitable deposition technique.

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

The terms “approximately,” “about,” and “substantially” as used herein may mean within a range of normal tolerance in the art, such as within 2 standard deviations of the mean, within ±20% of a target dimension in some embodiments, within ±10% of a target dimension in some embodiments, within ±5% of a target dimension in some embodiments, within ±2% of a target dimension in some embodiments, within ±1% of a target dimension in some embodiments, and yet within ±0.1% of a target dimension in some embodiments. The terms “approximately” and “about” may include the target dimension. Unless specifically stated or obvious from context, all numerical values described herein are modified by the term “about.”

As used herein, a range includes all the values within the range. For example, a range of 1 to 10 may include any number, combination of numbers, sub-range from the numbers of 1, 2, 3, 4, 5, 6, 7, 8, 9, and 10 and fractions thereof.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. A resistive random-access memory (RRAM) device, comprising:
a first electrode comprising a first electrode material;
a switching oxide layer comprising a switching oxide; and
a second electrode fabricated on the switching oxide layer, wherein the first electrode material is not reactive to the switching oxide, wherein the second electrode comprises a second electrode material that is reactive to the switching oxide, and wherein the second electrode material comprises at least one of tantalum (Ta), hafnium (Hf), tungsten (W), molybdenum (Mo), zirconium (Zr), or niobium (Nb).

2. The RRAM device of claim 1, wherein the first electrode is fabricated on a substrate, and wherein the substrate comprises at least one of silicon carbide (SiC), aluminum nitride (AlN), gallium nitride (GaN), or gallium oxide (Ga₂O₃).

3. The RRAM device of claim 1, wherein the switching oxide comprises at least one of HfOₓ, TaOy, or ZrO_{z}, wherein x≤2.0, y≤2.5, z≤2.0.

4. The RRAM device of claim 3, wherein the first electrode material comprises at least one of platinum (Pt), iridium (Ir), palladium (Pd), carbon (graphene), chromium (Cr), ruthenium (Ru), TiN, TaN, or a conductive ceramic.

5. The RRAM device of claim 4, wherein the conductive ceramic comprises at least one of RuO₂, Bi₂Ru₂O₇, or Bi₂Ir₂O₇.

6. The RRAM device of claim 1, wherein the second electrode material comprises W.

7. The RRAM device of claim 6, wherein the first electrode material comprises at least one of graphene, Ru, or Cr.

8. The RRAM device of claim 1, wherein the RRAM device further comprises a first interface layer positioned between the first electrode and the switching oxide, and wherein the first interface layer comprises a first oxide that is more chemically stable than the switching oxide and an oxide of the second electrode material.

9. The RRAM device of claim 8, wherein the first oxide comprises at least one of Al₂O₃, Y₂O₃, or MgO.

10. The RRAM device of claim 1, further comprising a second interface layer fabricated between the second electrode and the switching oxide layer, wherein the second interface layer comprises a discontinuous film of a second oxide that is more chemically stable than the switching oxide and an oxide of the second electrode material.

11. The RRAM device of claim 10, wherein the second oxide comprises at least one of Al₂O₃, Y₂O₃, or MgO.

12. The RRAM device of claim 1, further comprising a third interface layer in the switching oxide layer, wherein the third interface layer comprises a third oxide that is more chemically stable than the switching oxide and the oxide of the second electrode material.

13. The RRAM device of claim 12, wherein the third interface layer comprises a discontinuous film of the third oxide, and wherein the third oxide comprises at least one of Al₂O₃, Y₂O₃, or MgO.

14. A method for fabricating a resistive random-access memory (RRAM) device, the method comprising:
fabricating a first electrode comprising a first electrode material;
fabricating a switching oxide layer comprising a switching oxide; and
fabricating a second electrode fabricated on the switching oxide layer, wherein the first electrode material is not reactive to the switching oxide, wherein the second electrode comprises a second electrode material that is reactive to the switching oxide, and wherein the second electrode material comprises at least one of tantalum (Ta), hafnium (Hf), tungsten (W), molybdenum (Mo), zirconium (Zr), or niobium (Nb).

15. The method of claim 14, wherein fabricating the first electrode comprises fabricating the first electrode on a substrate, and wherein the substrate comprises at least one of silicon carbide (SiC), aluminum nitride (AlN), gallium nitride (GaN), or gallium oxide (Ga₂O₃).

16. The method of claim 14, wherein the switching oxide comprises at least one of HfOₓ, TaO_{y}, or ZrO_{z}, wherein x≤2.0, y≤2.5, z≤2.0.

17. The method of claim 14, wherein the first electrode material comprises at least one of platinum (Pt), iridium (Ir), palladium (Pd), carbon, chromium (Cr), ruthenium (Ru), TiN, TaN, or a conductive ceramic.

18. The method of claim 17, wherein the conductive ceramic comprises at least one of RuO₂, Bi₂Ru₂O₇, or Bi₂Ir₂O₇.

19. The method of claim 14, wherein the second electrode material comprises W, and wherein the first electrode material comprises at least one of graphene, Ru, or Cr.

20. The method of claim 14, further comprises fabricating an interface layer on the first electrode by depositing a discontinuous layer of an oxide that is more chemically stable than the switching oxide.
